(19) United States
(12) Patent Application Publication
(10) Pub. No.: US 2011/0032673 A1
(43) Pub. Date: Feb. 10, 2011

(54) Display Apparatus

(75) Inventors: Masaya NAKAMICHI, Kyoto (JP); Masanori Sakakibara, Nara (JP)

Correspondence Address: NDQ&M WATCHSTONE LLP, 300 NEW JERSEY AVENUE, NW, FIFTH FLOOR, WASHINGTON, DC, 20001, US

(73) Assignee: Sanyo Electric Co., Ltd., Osaka (JP)

(21) Appl. No.: 12/851,791

(22) Filed: Aug. 6, 2010

(30) Foreign Application Priority Data
Aug. 7, 2009 (JP) 2009-184356

(51) Int. Cl. H05K 7/20

(52) U.S. Cl. 361/694

(57) ABSTRACT

A display apparatus has a display unit, a housing which accommodates the display unit, a transparent component arranged at a front side of the display unit, and a cover component which generates an air flow between the transparent component and the display unit, the cover component is removable to the housing.

This application is based on Japanese Patent Application No. 2009-184356 filed on Aug. 7, 2009, the contents of which are hereby incorporated by reference.

### BACKGROUND OF THE INVENTION

1. Field of the Invention

The present invention relates to a display apparatus having a composition for cooling a display unit, or a cover component for cooling the display unit.

2. Description of Related Art

In recent years, a display apparatus which employs a liquid crystal panel as a display unit is becoming the majority. Also, a display apparatus adapted for use under a direct sunlight irradiated environment is widely developed. For example, in a published patent application (US 2009-147170A1), a display apparatus equipped with a fan for generating an air flow in a front side of a liquid crystal panel is disclosed.

Sometimes, a user may want to use a display apparatus regularly used indoors in a sunlight irradiating environment such as outdoors or a place near the window.

Such user may have to purchase a display apparatus having a cooling mechanism such as fan. However, when using it in an indoor ordinary temperature environment, such mechanism is unnecessary. Despite this, an existence of cooling mechanism makes the display apparatus unnecessarily large, and an increase in weight makes inconvenient for carrying.

### SUMMARY OF THE INVENTION

A display apparatus according to present invention comprises a display unit; a housing which accommodates the display unit; a transparent component arranged at a front side of the display unit, and a cover component which generates an air flow between the transparent component and the display unit, the cover component is removable to the housing.

A cover component removable to a housing of a display apparatus having a display unit, comprising:

a transparent component which covers a front side of the display unit, and

an air-flow generating means, which generates a compulsive air-flow by the surface of the transparent component.

### BRIEF DESCRIPTION OF THE DRAWINGS

FIG. 1 shows a main portion of a display apparatus 100 when a cover component 10 is not equipped. (a) is a front-view and (b)

side cross-sectional view.

FIG. 2 shows a display apparatus 100 when a cover component 10 is equipped to a housing 1. (a) is a front-view and (b) is side cross-sectional view.

FIG. 3 is an A-A′ cross-sectional view (see FIG. 2) of a cover component 10 viewed from the front side.

### DETAILED DESCRIPTION OF PREFERRED EMBODIMENTS

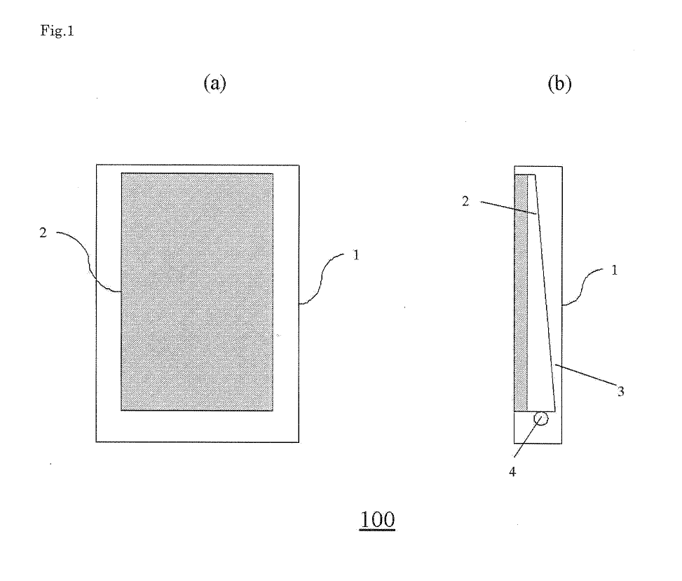

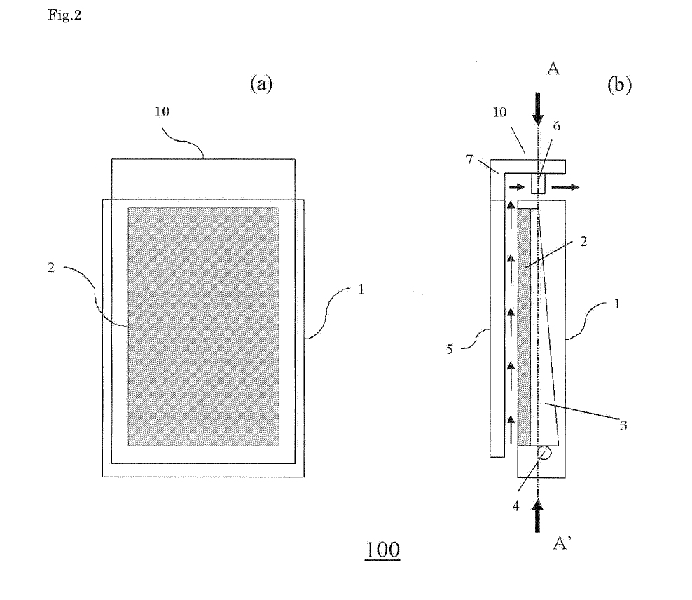

FIG. 1 and FIG. 2 shows a composition of a display apparatus 100 which is an embodiment of the present invention.

FIG. 1 shows a main portion of a display apparatus 100 when a cover component 10 is not equipped. (a) shows the apparatus 100 viewed from the front side (display surface side), and (b) is its side cross-sectional view.

The main portion of the apparatus 100 is constituted by a display panel 2, a light-guide plate 3, a light source 4 and a housing 1 which accommodates them.

The display panel 2 displays an image and is consisted by liquid crystal panel. The light source 4 is consisted by halogen lamps or CCFL (Cold Cathode Fluorescent Lamps) etc. The light-guide plate 3 leads a light from the light source 4 to the display panel 2. The geometry of the plate 3 is designed so that the luminosity of the light from the light source 4 becomes uniform over the whole display panel 2 surfaces.

Although it is not shown in the figures, in the housing 1, a circuit for controlling the display panel 2, a circuit for driving the light source 4, the circuit that performs signal processing of the image signal which should be displayed with the display panel 2, the circuit for processing the audio signal outputted from the speaker which is not illustrated, etc. are built in. Moreover, you may include the circuit for controlling the fan 7 who mentions later.

FIG. 2 shows a display apparatus 100 when a cover component 10 is equipped to a housing 1. (a) is a front-view and (b) is side cross-sectional view.

The cover component 10 comprises a transparent component 5, a fan 6, a connecting component 7, etc. The transparent component 5 is consisted by glass or a transparent plastic, for example. When the cover component 10 is equipped to the housing 1, the component 10 is constituted so that the transparent component 5 is arranged in front of the display surface of the display panel 2. The transparent component 5 is made transparent in order to make the display surface of the display panel 2 viewable from the front side of the display apparatus 100.

Further, the cover component 10 is constituted so that the fan 6 is arranged on the upper side of the display panel 2 and the housing 1, when the component 10 is equipped to the housing 1. When the fan 6 is driven while the component 10 is equipped as such, an air-flow is generated between the transparent component 5 and the display panel 2 as shown in FIG. 2 (b). That is, an air-flow from bottom up is generated in the display surface side of the panel 2. Thereby, the display surface side is made cool.

Further, the transparent component 5 and the fan 6 are connected through the connecting component 7. Thereby, the transparent component 5 and the fan 6 are removable integrally from the housing 1.

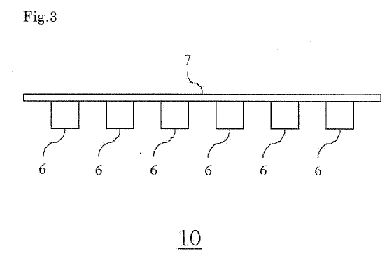

FIG. 3 is an A-A′ cross-sectional view (see FIG. 2) of a cover component 10 viewed from the front side. When the cover component 10 is equipped to the housing 1 as shown in FIG. 3, a plurality of the fans 6 will be arranged in the horizontal direction on the upper side of the display apparatus 100.

According the display apparatus 100 described above, since the cover component 10 is removable from the main portion, the cover component 10 can be detached during an indoor use of the apparatus 100. Thereby, weight and size of the apparatus 100 can be reduced during the indoor use, and thus the arrangement space is reduced and a conveyance is eased. Further, during the outdoor use, or a usage under a high temperature such as window side, the cover component 10 can be attached to the main portion of the apparatus 100. Thus, the display unit is cooled appropriately during the outdoor use etc.

The embodiment of the present invention is described as above. However, the scope of the present invention is not limited thereto, and the present invention may be implemented by being subjected to various modifications without departing from the gist of the present invention.

For example, the transparent component 5 may have a filter for intercepting the sunlight, such as an ultraviolet-rays filter, an infrared filter, or a polarizing plate.

Although it is not illustrated in above figures, a fan may be arranged under the display panel 2. Thereby, a powerful air-flow can be generated in front side of the display panel 2.

When it is detected that the cover component 10 is equipped to the housing 1, the fan 7 may be driven automatically (i.e. the fan 7 may begin to rotate). Or, the fan 7 may be activated when a power is supplied from the main portion of the apparatus 100. The fan 7 may be activated only when a temperature sensor detects that the temperature is beyond a predetermined value. The fan 7 may be activated triggered by an operation of a manual switch or remote control by a user.

Although, the present invention is described based the above display apparatus 100 having a vertically long display surface, the present invention can be applied to a display apparatus having a horizontally long display surface.

Although the LCD panel is described as an example of the display unit in above, a plasma panel, organic electroluminescence, electronic paper, CRT, may be applied as well.

What is claimed is:

1. A display apparatus comprising:
a display unit;
a housing which accommodates the display unit;
a transparent component arranged at a front side of the display unit, and
a cover component which generates an air flow between the transparent component and the display unit, the cover component is removable to the housing.

2. A cover component removable to a housing of a display apparatus having a display unit, comprising:
a transparent component which covers a front side of the display unit, and
an air-flow generating means, which generates a compulsive air-flow by the surface of the transparent component.
